(19) United States
(12) Patent Application Publication
(10) Pub. No.: US 2024/0421197 A1
(43) Pub. Date: Dec. 19, 2024

(54) SEMICONDUCTOR DEVICE

(71) Applicant: FUJI ELECTRIC CO., LTD., Kawasaki-shi (JP)

(72) Inventor: Takahide TANAKA, Matsumoto-city (JP)

(73) Assignee: FUJI ELECTRIC CO., LTD., Kawasaki-shi (JP)

(21) Appl. No.: 18/642,222

(22) Filed: Apr. 22, 2024

(30) Foreign Application Priority Data
Jun. 15, 2023 (JP) 2023-098500

(51) Int. Cl. H01L 29/40; H01L 29/06; H01L 29/78; H03K 17/567; H03K 19/0185

(52) U.S. Cl. CPC H01L 29/402; H01L 29/063; H01L 29/7816; H03K 17/567; H03K 19/018507; H03K 2217/0063; H03K 2217/0072

(57) ABSTRACT

A semiconductor device includes: a base body of a first conductivity-type; a first well region of a second conductivity-type provided in the base body and including a high-side circuit; a first voltage blocking region of the second conductivity-type provided along a circumference of the first well region; a second voltage blocking region of the first conductivity-type provided on an outer circumferential side of the first voltage blocking region; a first level shift element provided to encompass a part of the first voltage blocking region; a first isolation region of the first conductivity-type provided to surround a circumference of the first level shift element; and a field plate provided over the first voltage blocking region and the first isolation region with an insulating film interposed, the field plate having a first distance from the first isolation region greater than a second distance from the first voltage blocking region.

### CROSS-REFERENCE TO RELATED APPLICATION

This application claims benefit of priority under 35 USC 119 based on Japanese Patent Application No. 2023-098500 filed on Jul. 15, 2023, the entire contents of which are incorporated by reference herein.

### BACKGROUND OF THE INVENTION

### 1. Field of the Invention

The present invention relates to semiconductor devices.

### 2. Description of the Related Art

JP6798377B2 and JP3917211B2 each disclose a structure in which a high-voltage integrated circuit (HVIC) includes a high-voltage junction termination (HVJT) integrated with a high-voltage n-channel MOSFET (HVNMOS), and the HVNMOS is surrounded by a p⁻-type slit region so as to be electrically isolated from the HVJT, which is also referred to as a “divided RESURF structure”. This structure provides a parasitic MOS transistor in which the p⁻-type slit region serves as a channel and a field plate located immediately over the p⁻-type slit region serves as a gate.

JP6009341B2 discloses a configuration in which a field plate is divided onto a HVIT and a HVNMOS so as to avoid a provision of a parasitic MOS. JP6134219B2 discloses a configuration in which a start point of a field plate is connected to a drain potential of a HVNMOS so as to suppress an operation of a parasitic MOS.

JP6414861B2 discloses a configuration in which a p⁻-type slit region is completely covered with two field plates so as to enhance resistance to surface electrification. JP2021-114527A1 discloses a configuration in which a p-type layer having a high impurity concentration is provided in a part of a p⁻-type slit region so as to avoid a formation of an inversion layer of a parasitic MOS.

JP5321768B1 discloses a configuration in which a start point of a field plate is connected to a VS potential so as to suppress an operation of a parasitic MOS.

The conventional divided RESURF structure as described above leads a leak current flows between the HVJT and the HVNMOS when the parasitic MOS operates, which impedes a normal operation of the HVIC. There is great deal of room for improvement in suppression of operation of such a parasitic MOS.

### SUMMARY OF THE INVENTION

In view of the foregoing problems, the present invention provides a semiconductor device having a configuration capable of suppressing an operation of a parasitic element including a field plate as a constituent element.

An aspect of the present invention inheres in a semiconductor device including: a base body of a first conductivity-type; a first well region of a second conductivity-type provided in the base body and including a high-side circuit; a first voltage blocking region of the second conductivity-type having a lower impurity concentration than the first well region and provided into a circular state along a circumference of the first well region; a second voltage blocking region of the first conductivity-type provided into a circular state in contact with the first voltage blocking region on an outer circumferential side of the first voltage blocking region; a first level shift element provided to encompass a part of the first voltage blocking region; a first isolation region of the first conductivity-type provided to surround a circumference of the first level shift element; and a field plate provided over the first voltage blocking region and the first isolation region with an insulating film interposed, the field plate having a first distance from the first isolation region greater than a second distance from the first voltage blocking region.

### BRIEF DESCRIPTION OF THE DRAWINGS

FIG. 1 is a circuit diagram of a semiconductor device according to a first embodiment;

FIG. 2 is a plan view illustrating the semiconductor device according to the first embodiment;

FIG. 3 is a cross-sectional view taken along line A-A′ in FIG. 2;

FIG. 4 is a cross-sectional view taken along line B-B′ in FIG. 2;

FIG. 5 is a plan view illustrating a semiconductor device according to a second embodiment;

FIG. 6 is a cross-sectional view taken along line B-B′in FIG. 5;

FIG. 7 is a plan view illustrating a semiconductor device according to a third embodiment;

FIG. 8 is a plan view illustrating a semiconductor device according to a fourth embodiment;

FIG. 9 is a plan view illustrating a semiconductor device according to a fifth embodiment;

FIG. 10 is a plan view illustrating a semiconductor device according to a sixth embodiment;

FIG. 11 is a cross-sectional view taken along line B-B′in FIG. 10;

FIG. 12 is a cross-sectional view illustrating a semiconductor device according to a seventh embodiment;

FIG. 13 is a cross-sectional view illustrating a semiconductor device according to an eighth embodiment; and

FIG. 14 is a cross-sectional view illustrating a semiconductor device according to a ninth embodiment.

### DETAILED DESCRIPTION

With reference to the drawings, first to ninth embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Moreover, in some drawings, portions are illustrated with different dimensional relationships and proportions. The first to ninth embodiments described below merely illustrate schematically devices and methods for specifying and giving shapes to the technical idea of the present invention, and the span of the technical idea is not limited to materials, shapes, structures, and relative positions of elements described herein.

In the specification, a “carrier-supply region” means a semiconductor region which supplies majority carriers as a main current. The carrier-supply region is assigned to a semiconductor region which will be a source region in a field-effect transistor (FET) or a static induction transistor (SIT), an emitter region in an insulated-gate bipolar transistor (IGBT), and an anode region in a diode, a static induction (SI) thyristor or a gate turn-off (GTO) thyristor. A “carrier-reception region” means a semiconductor region which receive the majority carriers as the main current. The carrier-reception region is assigned to a semiconductor region which will be the drain region in the FET or the SIT, the collector region in the IGBT, and the cathode region in the diode, the SI thyristor or the GTO thyristor.

In the specification, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is exemplified a case where a first conductivity-type is an p-type and a second conductivity-type is a n-type. However, the relationship of the conductivity-types may be inverted to set the first conductivity-type to the n-type and the second conductivity-type to the p-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type” and “second conductivity-type” in the following description indicate the members and the regions formed of semiconductor materials without particular obvious limitations.

### First Embodiment

### Circuit of Semiconductor Device

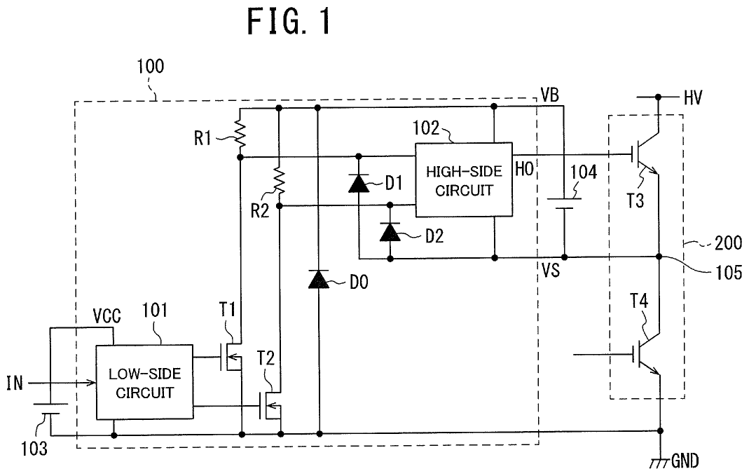

A semiconductor device according to a first embodiment is illustrated below with a high-voltage integrated circuit (HVIC) 100, as illustrated in FIG. 1. The HVIC 100 drives a power conversion unit 200 as a target to be driven for one phase of a power conversion bridge circuit, for example. The power conversion unit 200 includes a high-potential-side switching element T3 and a low-potential-side switching element T4 connected in series so as to implement a half-bridge circuit. While FIG. 1 illustrates the case in which the high-potential-side switching element T3 and the low-potential-side switching element T4 are each an IGBT, the respective elements may be any other power switching elements such as a metal-oxide-semiconductor field-effect-transistor (MOSFET).

A HV potential on a high-potential side is connected to a collector of the high-potential-side switching element T3. A ground potential (a GND potential) on a low-potential side is connected to an emitter of the low-potential-side switching element T4. A VS potential on the negative-electrode side of a power supply on a high-potential side (a high-potential-side power supply) 104 is connected to a connection point 105 between an emitter of the high-potential-side switching element T3 and a collector of the low-potential-side switching element T4. A load such as a motor (not illustrated) is also connected to the connection point 105.

The HVIC 100 applies, to a gate of the high-potential-side switching element T3, a drive signal for turning ON/OFF to drive the gate of the high-potential-side switching element T3 in accordance with an input signal IN from an external microcomputer or the like. The HVIC 100 includes a low-potential-side circuit (a low-side circuit) 101 and a high-potential-side circuit (a high-side circuit) 102. The low-side circuit 101 is connected to a VCC potential on a positive electrode side of a power supply on a low-potential side (a low-potential-side power supply) 103 and a GND potential on a negative electrode side of the low-potential-side power supply 103. The low-side circuit 101 is also connected to gates of level shift elements (level shifters) T1 and T2.

The low-side circuit 101 operates at the GND potential as a reference potential and at the VCC potential higher than the GND potential as a power-supply potential. The low-side circuit 101 generates an ON/OFF signal based on the GND potential in accordance with the input signal IN from the external microcomputer or the like, and outputs the generated signal to the respective gates of the level shift elements T1 and T2.

The respective level shift elements T1 and T2 execute a signal transmission between the low-side circuit 101 and the high-side circuit 102. The respective level shift elements T1 and T2 convert the ON/OFF signal based on the GND potential from the low-side circuit 101 into an ON/OFF signal based on the VS potential, and outputs the converted ON/OFF signal to the high-side circuit 102. The respective level shift elements T1 and T2 are each a high-voltage n-channel MOSFET, for example.

The GND potential is connected to a source of the level shift element T1. The high-side circuit 102 and one end of a level shift resistor R1 are connected to a drain of the level shift element T1. A VB potential on the positive-electrode side of the high-potential-side power supply 104 is connected to the other end of the level shift resistor R1. A cathode of a diode D1 is connected to the drain of the level shift element T1 and the one end of the level shift resistor R1. The high-side circuit 102 and the VS potential on the negative-electrode side of the high-potential-side power supply 104 are connected to an anode of the diode D1. The diode D1 has a function of avoiding an excessive reduction in drain potential (Dr potential) of the level shift element T1.

The GND potential is connected to a source of the level shift element T2. The high-side circuit 102 and one end of a level shift resistor R2 are connected to a drain of the level shift element T2. The VB potential on the positive-electrode side of the high-potential-side power supply 104 is connected to the other end of the level shift resistor R2. A cathode of a diode D2 is connected to the drain of the level shift element T2 and the one end of the level shift resistor R2. The high-side circuit 102 and the VS potential on the negative-electrode side of the high-potential-side power supply 104 are connected to an anode of the diode D2. The diode D2 has a function of avoiding an excessive reduction in drain potential (Dr potential) of the level shift element T2.

A cathode of a high-voltage diode D0, which is referred to as a high-voltage junction termination (HVJT), is connected to the VB potential on the positive-electrode side of the high-potential-side power supply 104. The GND potential is connected to an anode of the diode D0.

The high-side circuit 102 operates at the VS potential as a reference potential and at the VB potential higher than the VS potential as a power-supply potential. The high-side circuit 102 outputs a drive signal based on the VS potential to the gate of the high-potential-side switching element T3 in accordance with the ON/OFF signal from the respective level shift elements T1 and T2 so as to drive the gate of the high-potential-side switching element T3. The high-side circuit 102 includes a CMOS circuit of an n-channel MOSFET and a p-channel MOSFET at the output stage.

The VB potential is a maximum potential applied to the HVIC 100, and is kept higher than the VS potential by about 15 volts in a normal state not influenced by noise. The VS potential repeats a rise and a drop between the HV potential on the high-potential side (about 400 to 600 volts, for example) and the GND potential on the low-potential side when the high-potential-side switching element T3 and the low-potential-side switching element T4 are complementarily turned on and off, and varies between zero to several hundreds of volts. The VS potential can fall below zero.

### Structure of Semiconductor Device

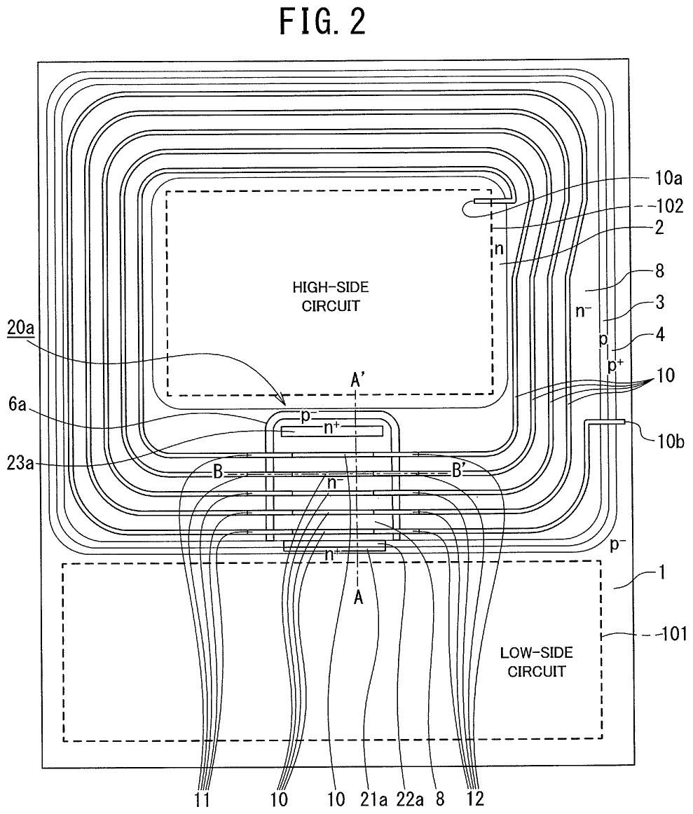

FIG. 2 illustrates a planar layout of the semiconductor device according to the first embodiment corresponding to the HVIC 100 illustrated in FIG. 1. The HVIC 100 includes a base body (a semiconductor chip) 1 of a first conductivity-type (p⁻-type). The base body 1 is made of a silicon (Si) substrate, for example. The base body 1 may be made of a semiconductor substrate including silicon carbide (SiC), a gallium nitride (GaN), a gallium oxide (Ga₂O₃), gallium arsenide (GaAs), or diamond (C). Alternatively, the base body 1 may include a semiconductor substrate of p⁻-type and an epitaxial layer of p⁻-type deposited on the semiconductor substrate.

The base body 1 may be fixed at the GND potential. A well region 2 of a second conductivity-type (n-type) is provided at the upper part of the base body 1. The well region 2 has a substantially rectangular planar pattern. The VB potential is applied to the well region 2. The well region 2 is provided with the high-side circuit (the high-side circuit region) 102. FIG. 2 omits the illustration of the respective elements included in the high-side circuit 102.

A voltage blocking region 8 of n⁻-type having a lower impurity concentration than the well region 2 is provided to surround the well region 2 in contact with each other. The voltage blocking region 8 is provided into a substantially circular state with an outline having a substantially rectangular planar pattern.

A voltage blocking region 3 of p-type is provided to surround the outer circumference of the voltage blocking region 8 in contact with each other. The voltage blocking region 3 is provided into a substantially circular state with an outline having a substantially rectangular planar pattern. The GND potential is applied to the voltage blocking region 3. The outer circumference of the voltage blocking region 3 is surrounded by the base body 1.

The p-n junction between the p-type voltage blocking region 3 and the n⁻-type voltage blocking region 8 implements a high-voltage junction termination (HVJT) (3, 8). The HVJT (3, 8) corresponds to the high-voltage diode D0 illustrated in FIG. 1. The HVIT (3, 8) is provided into a substantially circular state with an outline having a substantially rectangular planar pattern. The HVJT (3, 8) electrically isolates the high-side circuit 102 on the inner circumferential side of the HVJT (3, 8) from the low-side circuit (the low-side circuit region) 101 provided in the base body 1 on the outer circumferential side of the HVIT (3, 8). The provision of the HVJT (3, 8) can keep a normal operation if the potential of the high-side circuit 102 is led to be higher than the potential of the low-side circuit 101 by several hundreds of volts.

The low-side circuit 101 is located on the lower side the high-side circuit 102 in the plan view of FIG. 2 with the HVJT (3, 8) interposed. FIG. 2 omits the illustration of several kinds of elements implementing the low-side circuit 101.

As illustrated in FIG. 2, a level shift element 20a is formed integrally with a part of the HVJT (3, 8). The level shift element 20a is arranged to encompass a part of the voltage blocking region 8. The level shift element 20a corresponds to the level shift element T1 illustrated in FIG. 1. FIG. 2 omits the illustration of a level shift element corresponding to the level shift element T2 illustrated in FIG. 1.

The level shift element 20a is a high-voltage n-channel MOSFET (HVNMOS). The level shift element 20a includes a carrier-supply region (a source region) 21a of n⁺-type, a gate electrode 22a, and a carrier-reception region (a drain region) 23a of n⁺-type. The source region 21a, the gate electrode 22a, and the drain region 23a each have a straight planar pattern extending parallel to each other. A part of the voltage blocking region 8 interposed between the source region 21a and the drain region 23a serves as a drift region of the level shift element 20a.

An isolation region (a slit region) 6a of p⁻-type is provided so as to surround the circumference of the level shift element 20a. The isolation region 6a has a substantially U-shaped planar pattern with a bottom located toward the high-side circuit 102 and an opening located toward the low-side circuit 101. The respective ends of a pair of (two) straight parts connected to the bottom of the U-shaped isolation region 6a are in contact with the voltage blocking region 3. The semiconductor device according to the first embodiment thus has a structure in which the level shift element 20a is surrounded by the isolation region 6a so as to be electrically isolated from the HVJT (3, 8), which is referred to as a divided RESURF structure.

A field plate (10, 11, 12) is provided over the HVJT (3, 8) and the level shift element 20a. The field plate (10, 11, 12) has a function of leading a high-voltage applied inside the HVIC to a uniform potential distribution at a minimal current. The semiconductor device according to the first embodiment is illustrated below with a case in which the field plate (10, 11, 12) has a resistive field plate (RFP) structure (a resistive element).

The field plate (10, 11, 12) has a spiral planar pattern. A width of the field plate (10, 11, 12) in a direction perpendicular to the extending direction of the spiral of the field plate (10, 11, 12) is about one micrometer, for example. A gap between the spiral lines of the field plate (10, 11, 12) adjacent to each other in the direction perpendicular to the extending direction of the spiral of the field plate (10, 11, 12) is about one micrometer, for example.

While FIG. 2 illustrates the case in which the field plate (10, 11, 12) makes about five rounds, the number of the rounds of the field plate (10, 11, 12) to be made is not limited to the case as illustrated. The number of the rounds of the field plate (10, 11, 12) may be determined as appropriate depending on the width and the like of the voltage blocking region 8 in the direction perpendicular to the extending direction of the spiral of the field plate (10, 11, 12).

The VB potential, as an example of a first potential on the high-potential side, is connected to one end 10a on the inner circumferential side of the field plate (10, 11, 12). The first potential may be the VS potential, or may be the drain potential of the level shift element 20a. The drain potential of the level shift element 20a corresponds to a potential between the VB potential and the VS potential.

The ground potential (the GND potential), as an example of a second potential on the low-potential side lower than the first potential, is connected to the other end 10b on the outer circumferential side of the field plate (10, 11, 12). The second potential may be a potential different from the GND potential.

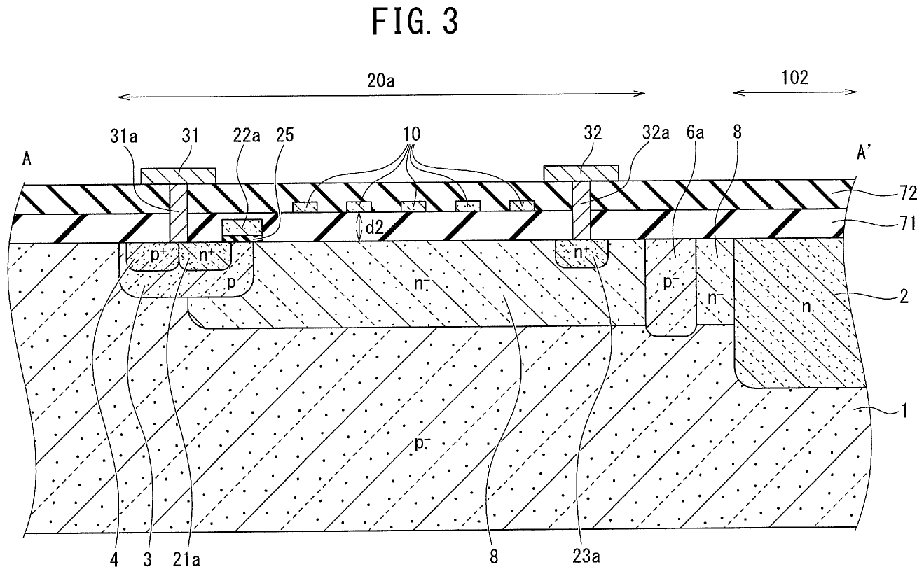

FIG. 3 is a cross-sectional view taken along line A-A′ passing across the level shift element 20a illustrated in FIG. 2. As illustrated in FIG. 3, the n-type well region 2 is provided at the upper part of the p⁻-type base body 1. The well region 2 is a diffusion layer to which n-type impurity ions are implanted. The well region 2 is provided with the high-side circuit 102.

The n⁻-type voltage blocking region 8 is provided at the upper part of the base body 1 so as to be in contact with the well region 2. The voltage blocking region 8 is a diffusion layer to which n-type impurity ions are implanted. The voltage blocking region 8 has a smaller depth than the well region 2. The p⁻-type isolation region 6a is provided at the upper part of the base body 1 to so as penetrate the voltage blocking region 8 in the depth direction to reach the base body 1. The isolation region 6a is a diffusion layer to which p-type impurity ions are implanted. The isolation region 6a has a greater depth than the voltage blocking region 8.

As illustrated in FIG. 3, the level shift element 20a is isolated from the n-type well region 2 by the p⁻-type isolation region 6a. A part of the voltage blocking region 8 isolated from the n-type well region 2 by the p⁻-type isolation region 6a serves as the drift region of the level shift element 20a. The upper part of the voltage blocking region 8 serving as the drift region of the level shift element 20a is provided with the n⁺-type drain region 23a. The drain region 23a is a diffusion layer to which n-type impurity ions are implanted. An insulating film 71 and an insulating film 72 are deposited on the top surface side of the drain region 23a. A drain electrode 32 is connected to the drain region 23a through a via 32a made of metal and the like provided in an opening (a contact hole) formed in the insulating film 71 and the insulating film 72. The drain electrode 32 may be made of metal mainly including aluminum (Al) or copper (Cu), for example.

The insulating film 71 as used herein can be a silicon oxide (SiO₂) film or a silicon nitride (Si₃N₄) film, or a composite film including these films. The insulating film 71 may be obtained by a chemical vapor deposition (CVD) method by use of gas including organic silicon compound such as tetraethoxysilane (TEOS), for example.

The insulating film 72 as used herein can be a silicon oxide film (a SiO₂ film) without containing impurity ions which is referred to as a non-doped silicate glass (NSG) film, a phosphosilicate glass film (a PSG film), or a borosilicate glass film (a BSG film). Alternatively, the insulating film 72 may be a single film of a borophosphosilicate glass film (a BPSG film) or a silicon nitride film (a Si₃N₄ film), or a composite film including some of the above films combined together as appropriate.

The p-type voltage blocking region 3 is provided at the upper part of the base body 1 so as to be in contact with the voltage blocking region 8 on the opposite side of the well region 2. The voltage blocking region 3 is a diffusion layer to which p-type impurity ions are implanted. A part of the voltage blocking region 3 in contact with the voltage blocking region 8 implementing the drift region of the level shift element 20a serves as a base region of the level shift element 20a.

The n⁺-type source region 21a is provided at the upper part of the voltage blocking region 3 serving as the base region of the level shift element 20a. The source region 21a is a diffusion layer to which n-type impurity ions are implanted. A contact region 4 of p⁺-type having a higher impurity concentration than the voltage blocking region 3 is provided at an upper part of the voltage blocking region 3 serving as the base region of the level shift element 20a so as to be in contact with the source region 21a. The contact region 4 is a diffusion layer to which p-type impurity ions are implanted.

A source electrode 31 is connected to the source region 21a and the contact region 4 through a via 31a made of metal and the like provided in an opening (a contact hole) formed in the insulating film 71 and the insulating film 72. The source electrode 31 may be made of metal mainly including aluminum (Al) or copper (Cu), for example.

The gate electrode 22a is provided on the top surface side of the voltage blocking region 3 interposed between the source region 21a and the voltage blocking region 8 with a gate insulating film 25 interposed. The gate insulating film 25 as used herein can be a single film of a silicon oxide film (a SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, an yttrium oxide (Y₂O₃) film, a hafnium oxide (HfO₂) film, a zirconium oxide (ZrO₂) film, a tantalum oxide (Ta₂O₅) film, or a bismuth oxide (Bi₂O₃) film, or a composite film including some of the above films stacked on one another. The gate electrode 22a can be made of a polysilicon layer (a doped polysilicon layer) heavily doped with either p-type or n-type impurity ions, or made from refractory metal such as titanium (Ti), tungsten (W), or nickel (Ni), for example.

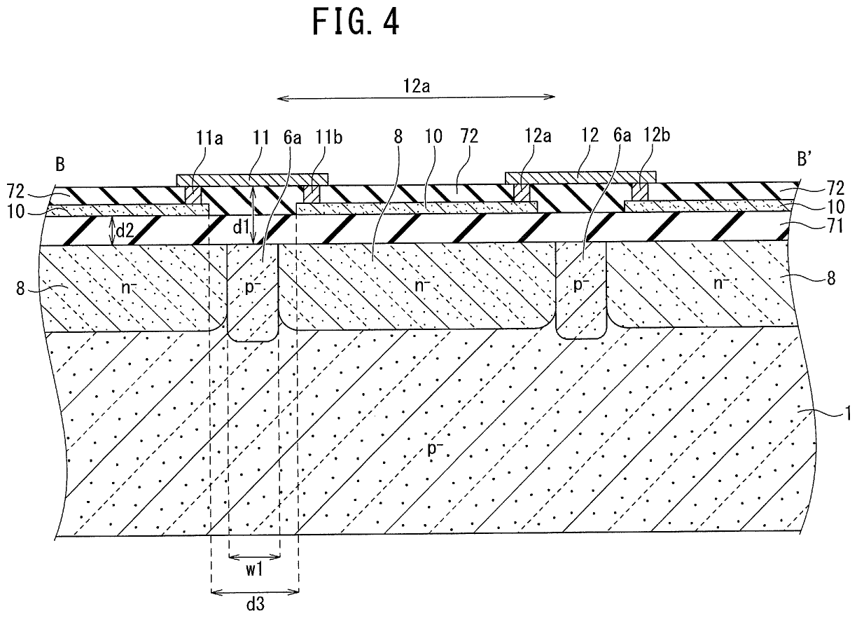

FIG. 4 is a cross-sectional view taken along line B-B′, perpendicular to line A-A′, passing across the level shift element 20a and a part of one of the spiral lines of the field plate (10, 11, 12). As illustrated in FIG. 4, the field plate (10, 11, 12) includes a first layer (a lower layer) 10 and second layers (upper layers) 11 and 12 provided over (on the upper side of) the first layer 10.

As illustrated in FIG. 2, the first layer 10 occupies a large part of the field plate (10, 11, 12) so as to be provided in the region excluding the parts passing over the isolation region 6a. As illustrated in FIG. 3 and FIG. 4, the first layer 10 is provided on the top surface side of the insulating film 71. As illustrated in FIG. 4, the first layer 10 is located over the voltage blocking region 8. The first layer 10 passes across the region on the upper side of the level shift element 20a. The first layer 10 is divided into parts over the isolation region 6a interposing the level shift element 20a. A distance (a gap) d3 between the divided parts of the first layer 10 is greater than a width w1 of the isolation region 6a. The first layer 10 is at least not arranged in a region over the isolation region 6a.

The first layer 10 is a resistive thin film including high-resistance polysilicon, for example. Either p-type or n-type impurity ions are implanted to the polysilicon included in the first layer 10 in a range of about 1×10¹⁷ cm⁻³ or greater and 1×10²⁰ cm⁻³ or less, for example. A sheet resistance value of the polysilicon included in the first layer 10 is about two kΩ/sq, for example. The first layer 10 may be made of a metal film manly including aluminum (Al) or copper (Cu), for example, instead of the resistive thin film.

As illustrated in FIG. 2, the second layers 11 and 12 are selectively (locally) provided over the isolation region 6a in the respective spiral lines of the field plate (10, 11, 12). FIG. 2 illustrates the case in which the respective second layers 11 and 12 have substantially the same width as the first layer 10 in the direction perpendicular to the extending direction of the spiral of the field plate (10, 11, 12). The width of the respective second layers 11 and 12 may be either greater than or smaller than the width of the first layer 10.

As illustrated in FIG. 4, the respective second layers 11 and 12 are deposited on the top surface side of the insulating film 72. The respective second layers 11 and 12 may be arranged on an insulating film (not illustrated) provided over the insulating film 72. The respective second layers 11 and 12 are located at least over the isolation region 6a. FIG. 4 illustrates the case in which the respective second layers 11 and 12 have substantially the same thickness as the first layer 10. The thickness of the respective second layers 11 and 12 may be either greater than or smaller than the thickness of the first layer 10.

Although not illustrated, an insulating film may be provided on respective top surface sides of the second layers 11 and 12 to cover the second layers 11 and 12. This insulating film can include the same material as that used for the insulating film 72 described above. This insulating film may also be provided to cover the top surface side of the insulating film 72.

The second layers 11 and 12 mainly include metal such as aluminum (Al) or copper (Cu), for example. The second layers 11 and 12 may include the same material as the source electrode 31 and the drain electrode 32, and can be prepared in the same step as that for preparing the source electrode 31 and the drain electrode 32 when including the common material. The second layers 11 and 12 may include material different from that included in the source electrode 31 and the drain electrode 32 instead. The second layers 11 and 12 include polysilicon, as in the case of the first layer 10. The second layers 11 and 12 may include material either the same as or different from that included in the first layer 10.

As illustrated in FIG. 4, one end and the other end of the second layer 11 are arranged to overlap with the respective divided ends of the first layer 10. The respective ends of the second layer 11 are electrically connected to the divided first layer 10 through vias 11a and 11b made of metal and the like provided in openings (contact holes) formed in the insulating film 72. One end and the other end of the second layer 12 are electrically connected to the divided first layer 10 through vias 12a and 12b made of metal and the like provided in openings (contact holes) formed in the insulating film 72. The first layer 10 and the respective second layers 11 and 12 are thus connected in series.

As illustrated in FIG. 4, a distance d1 between the respective second layers 11 and 12 and the isolation region 6a corresponds to a total of the thickness of the insulating film 71 and the thickness of the insulating film 72. A distance d2 between the first layer 10 and the voltage blocking region 8 corresponds to the thickness of the insulating film 71. The distance d1 between the respective second layers 11 and 12 and the isolation region 6a is thus greater than the distance d2 between the first layer 10 and the voltage blocking region 8.

As illustrated in FIG. 4, a parasitic n-type MOSFET is implemented by the p⁻-type isolation region 6a serving as a channel (a channel-forming region), a part of the voltage blocking region 8 serving as a source implementing the drift region of the level shift element 20a interposed by the isolation region 6a, a part of the voltage blocking region 8 serving as a drain located on the opposite side of the part serving as the source of the voltage blocking region 8 in the isolation region 6a, and a part of the field plate (10, 11, 12) serving as a gate located immediately over the isolation region 6a.

The semiconductor device according to the first embodiment has the configuration in which the distance d1 between the respective second layers 11 and 12 and the isolation region 6a is greater than the distance d2 between the first layer 10 and the voltage blocking region 8. This configuration can enhance a gate threshold voltage of the parasitic n-type MOSFET, so as to suppress the operation of the parasitic n-type MOSFET, as compared with a case of, for example, using a field plate having a constant distance from each of the isolation region 6a and the voltage blocking region 8. The semiconductor device according to the first embodiment can exhibit the sufficient effects even if, for example, a voltage between the field plate (10, 11, 12) and the isolation region 6a (a gate voltage of the parasitic n-type MOSFET) is temporarily biased by noise. Further, the gate threshold voltage of the parasitic MOS can be increased as the distance d1 between the respective second layers 11 and 12 and the isolation region 6a is increased, so as to greatly enhance the effect of suppressing the operation of the parasitic MOS.

Further, as illustrated in the planar view of FIG. 2, the field plate (10, 11, 12) as described above can cover the region equal to that in the case of using the field plate with the constant distance from each of the isolation region 6a and the voltage blocking region 8, so as to keep the resistance to surface electrification.

Further, the semiconductor device according to the first embodiment with the configuration described above can keep current consumption of the field plate (10, 11, 12) small since the second layers 11 and 12 are locally arranged only over the region including the isolation region 6a regardless of whether the first layer 10 is made of polysilicon while the second layers 11 and 12 are each made of metal. This configuration thus can enhance the gate threshold voltage of the parasitic n-type MOSFET, so as to suppress the operation of the parasitic n-type MOSFET with no necessity of making a great change of the fundamental characteristics of the field plate (10, 11, 12).

### Second Embodiment

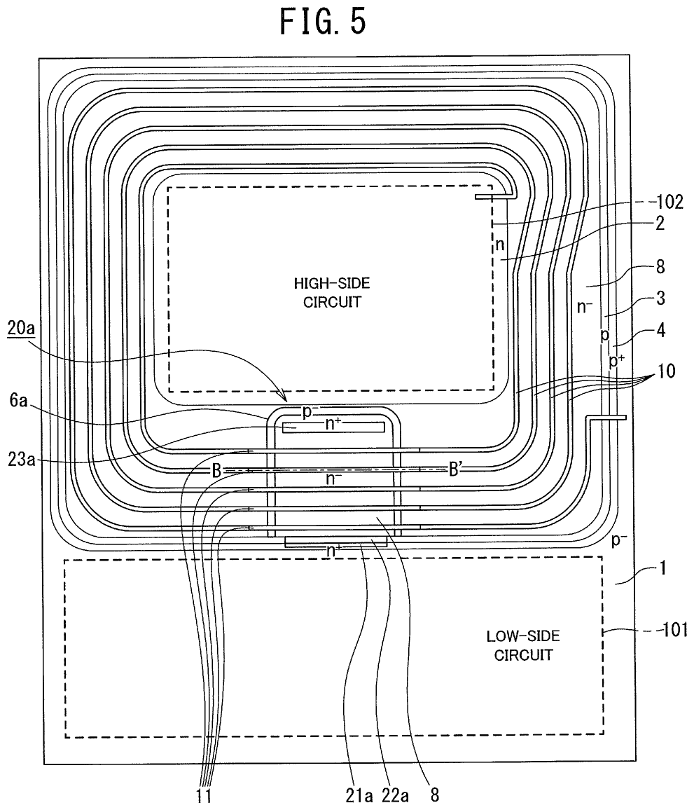

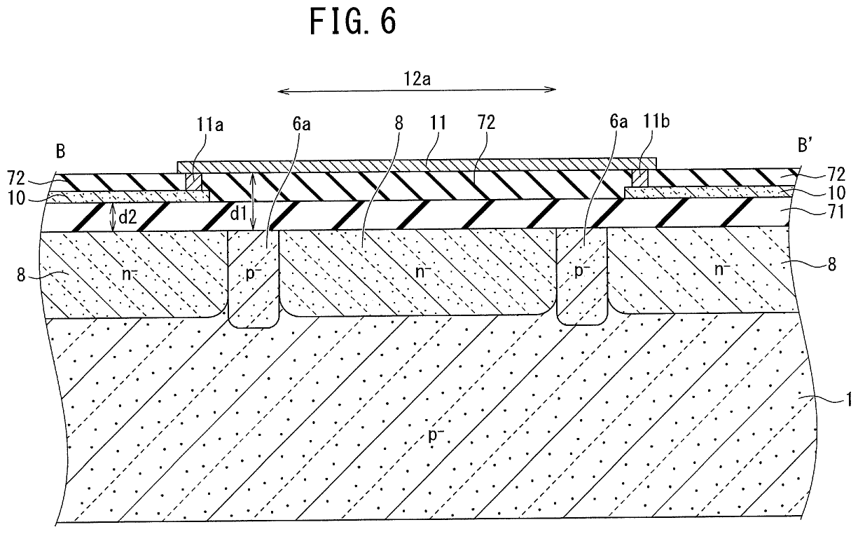

FIG. 5 is a plan view illustrating a semiconductor device according to a second embodiment, and FIG. 6 is a cross-sectional view taken along line B-B′ in FIG. 5. As illustrated in FIG. 5 and FIG. 6, the semiconductor device according to the second embodiment differs from the semiconductor device according to the first embodiment in that the second layer 11 of the field plate (10, 11) provided over the HVJT (3, 8) and the level shift element 20a is arranged to be elongated across the upper side of the isolation region 6a and the level shift element 20a.

As illustrated in FIG. 5 and FIG. 6, the field plate (10, 11) includes the first layer 10 and the second layer 11 arranged over the first layer 10. As illustrated in FIG. 6, the first layer 10 is divided at a position over the isolation region 6a and the voltage blocking region 8 implementing the drift region of the level shift element 20a interposed by the isolation region 6a. The first layer 10 is not provided over the isolation region 6a or the voltage blocking region 8 implementing the drift region of the level shift element 20a.

The second layer 11 is selectively (locally) arranged from a part over the isolation region 6a to a part over the voltage blocking region 8 implementing the drift region of the level shift element 20a. One end and the other end of the second layer 11 are electrically connected to the divided first layer 10 through the vias 11a and 11b made of metal provided in the openings (the contact holes) of the insulating film 72.

The distance d1 between the second layer 11 and each of the isolation region 6a and the level shift element 20a is greater than the distance d2 between the first layer 10 and the voltage blocking region 8 excluding the region corresponding to the level shift element 20a. The other structures of the semiconductor device according to the second embodiment are the same as those of the semiconductor device according to the first embodiment, and overlapping explanations are not repeated below.

The semiconductor device according to the second embodiment has the configuration in which the distance d1 between the second layer 11 and the isolation region 6a is greater than the distance d2 between the first layer 10 and the voltage blocking region 8 excluding the part corresponding to the level shift element 20a. This configuration can enhance the gate threshold voltage of the parasitic n-type MOSFET, so as to suppress the operation of the parasitic n-type MOSFET with no necessity of making a great change of the fundamental characteristics of the field plate (10, 11), as compared with a case of using a field plate having a constant distance from each of the isolation region 6a and the voltage blocking region 8.

The use of polysilicon for the first layer 10 of the field plate (10, 11) gradually decreases the voltage of the first layer 10 from the high-potential side to the low-potential side. Instead, the configuration in which the second layer 11 is made of metal and arranged to be elongated across the upper side of the isolation region 6a and the level shift element 20a keeps the potential of the field plate (10, 11) provided with the second layer 11 constant, so as to keep the entire potential along the level shift element 20a more evenly in the direction in which the second layer 11 passes across the level shift element 20a.

### Third Embodiment

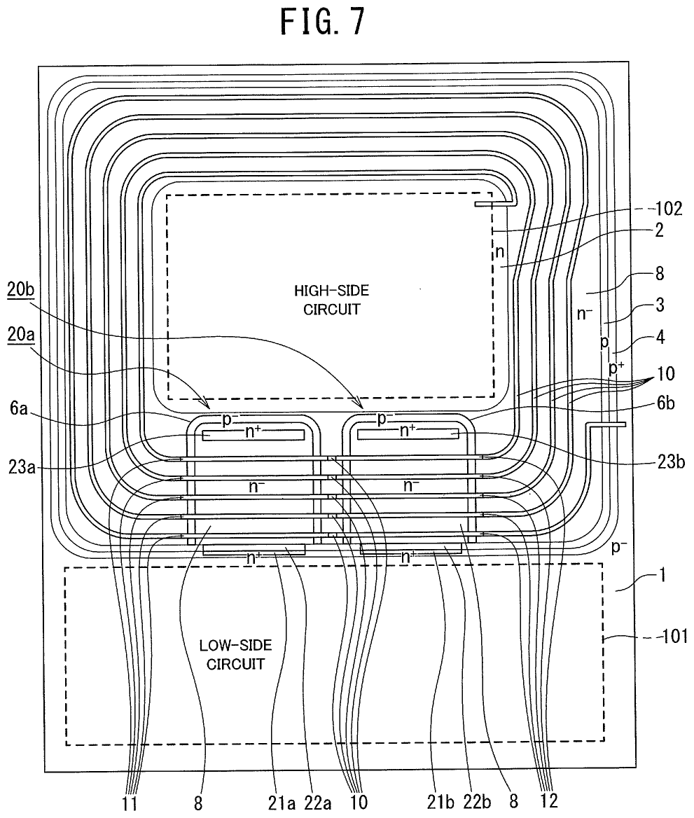

A semiconductor device according to a third embodiment differs from the semiconductor device according to the first embodiment in that a plurality of (two) level shift elements 20a and 20b are provided integrally with a part of the HVJT (3, 8), as illustrated in FIG. 7. The level shift elements 20a and 20b are arranged next to each other on one side of the rectangular planar pattern of the HVJT (3, 8). The arranged positions of the respective level shift elements 20a and 20b are not limited to the case as illustrated. For example, the respective level shift elements 20a and 20b may be arranged on the sides opposite to each other in the rectangular planar pattern of the HVJT (3, 8).

The level shift element 20b has a structure similar to that of the level shift element 20a. The level shift element 20b includes an n⁺-type source region 21b, a gate electrode 22b, and an n⁺-type drain region 23b. The source region 21b, the gate electrode 22b, and the drain region 23b each have a straight planar pattern extending parallel to each other. A part of the voltage blocking region 8 interposed between the source region 21b and the drain region 23b serves as a drift region of the level shift element 20b.

An isolation region 6b of p⁻-type is provided so as to surround the circumference of the level shift element 20b. The isolation region 6b electrically isolates the level shift element 20b from the well region 2.

The field plate (10, 11, 12) is provided over the HVIT (3, 8) and the level shift elements 20a and 20b. The field plate (10, 11, 12) includes the first layer 10 and the second layers 11 and 12 provided over the first layer 10. The second layer 11 is arranged to be elongated across the upper side of the isolation region 6a and the level shift element 20a. The second layer 12 is arranged to be elongated across the upper side of the isolation region 6b and the level shift element 20b. The other structures of the semiconductor device according to the third embodiment are the same as those of the semiconductor device according to the first embodiment, and overlapping explanations are not repeated below.

The semiconductor device according to the third embodiment has the configuration in which the distance between the second layer 11 and the isolation region 6a and the distance between the second layer 12 and the isolation region 6b are each greater than the distance between the first layer 10 and the voltage blocking region 8 excluding the regions corresponding to the level shift elements 20a and 20b. This configuration can enhance the gate threshold voltage of the parasitic n-type MOSFET, so as to suppress the operation of the parasitic n-type MOSFET with no necessity of making a great change of the fundamental characteristics of the field plate (10, 11, 12), as compared with a case of using a field plate having a constant distance from each of the respective isolation regions 6a and 6b and the voltage blocking region 8.

The use of polysilicon for the first layer 10 of the field plate (10, 11, 12) gradually decreases the voltage of the first layer 10 from the high-potential side to the low-potential side. Instead, the configuration in which the respective second layers 11 and 12 are made of metal and arranged to be elongated across the upper side of the isolation regions 6a and 6b and the level shift elements 20a and 20b keeps the potential of the field plate (10, 11, 12) provided with the second layers 11 and 12 constant, so as to keep the entire potential along the respective level shift elements 20a and 20b more evenly in the direction in which the second layers 11 and 12 pass across the level shift elements 20a and 20b.

### Fourth Embodiment

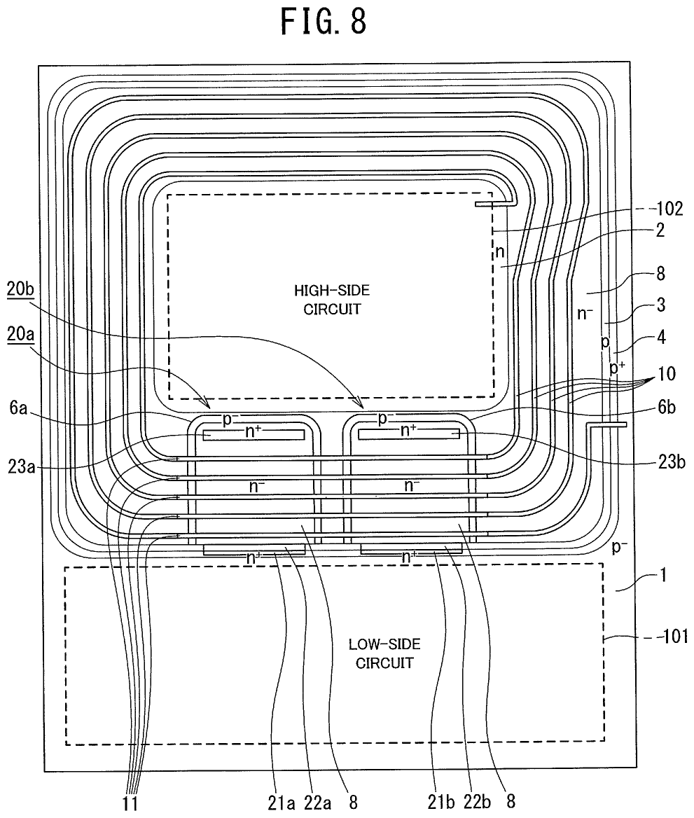

A semiconductor device according to a fourth embodiment has a configuration common to that of the semiconductor device according to the third embodiment illustrated in FIG. 7 in that the plural (two) level shift elements 20a and 20b are provided integrally with a part of the HVIT (3, 8), as illustrated in FIG. 8. The semiconductor device according to the fourth embodiment differs from the semiconductor device according to the third embodiment illustrated in FIG. 7 in that the second layer 11 of the field plate (10, 11) is provided to be continuously elongated across the upper side of each of the plural level shift elements 20a and 20b and the plural isolation regions 6a and 6b surrounding the corresponding level shift elements 20a and 20b, as illustrated in FIG. 8.

The field plate (10, 11) is provided over the HVIT (3, 8) and the respective level shift elements 20a and 20b. The field plate (10, 11) includes the first layer 10 and the second layer 11 arranged over the first layer 10. The second layer 11 is provided to be elongated across the upper side of the respective isolation regions 6a and 6b and the respective level shift elements 20a and 20b. The other structures of the semiconductor device according to the fourth embodiment are the same as those of the semiconductor device according to the third embodiment, and overlapping explanations are not repeated below.

The semiconductor device according to the fourth embodiment has the configuration in which the distance between the second layer 11 and the respective isolation regions 6a and 6b is greater than the distance between the first layer 10 and the voltage blocking region 8 excluding the region corresponding to the respective level shift elements 20a and 20b. This configuration can enhance the gate threshold voltage of the parasitic n-type MOSFET, so as to suppress the operation of the parasitic n-type MOSFET with no necessity of making a great change of the fundamental characteristics of the field plate (10, 11), as compared with a case of using a field plate having a constant distance from each of the respective isolation regions 6a and 6b and the voltage blocking region 8.

The use of polysilicon for the first layer 10 of the field plate (10, 11) gradually decreases the voltage of the first layer 10 from the high-potential side to the low-potential side. Instead, the configuration in which the second layer 11 is made of metal and arranged to be elongated continuously over the respective isolation regions 6a and 6b and the respective level shift elements 20a and 20b can keep the potential along the respective level shift elements 20a and 20b in the direction in which the second layer 11 passes across the respective level shift elements 20a and 20b.

### Fifth Embodiment

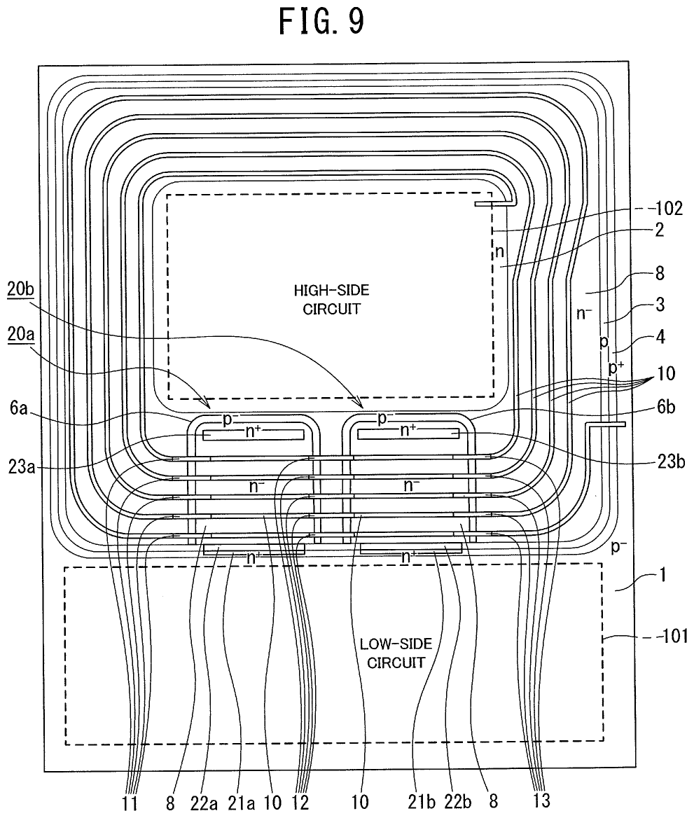

A semiconductor device according to a fifth embodiment has a configuration common to that of the semiconductor device according to the fourth embodiment illustrated in FIG. 8 in including the plural level shift elements 20a and 20b and the plural isolation regions 6a and 6b arranged to surround the corresponding level shift elements 20a and 20b, as illustrated in FIG. 9. The semiconductor device according to the fifth embodiment differs from the semiconductor device according to the fourth embodiment illustrated in FIG. 8 in that the second layers 11, 12, and 13 of the field plate (10, 11, 12, 13) do not pass across the respective level shift elements 20a and 20b but are locally provided over the respective isolation regions 6a and 6b, as illustrated in FIG. 9.

The field plate (10, 11, 12, 13) is provided over the HVJT (3, 8) and the respective level shift elements 20a and 20b. The field plate (10, 11, 12, 13) includes the first layer 10 and the second layers 11, 12, and 13 arranged over the first layer 10. The second layer 11 is provided to be elongated across one of the pair of the straight parts of the planar pattern of the isolation region 6a. The second layer 12 is provided to be elongated across the other straight part of the planar pattern of the isolation region 6a, a part of the voltage blocking region 8 between the isolation region 6a and the isolation region 6b, and one of the pair of the straight parts of the planar pattern of the isolation region 6b. The second layer 13 is provided to be elongated across the other straight part of the planar pattern of the isolation region 6b. The other structures of the semiconductor device according to the fifth embodiment are the same as those of the semiconductor device according to the fourth embodiment, and overlapping explanations are not repeated below.

The semiconductor device according to the fifth embodiment has the configuration in which the distance between the respective second layers 11, 12, and 13 and the respective isolation regions 6a and 6b is greater than the distance between the first layer 10 and the voltage blocking region 8 excluding the region corresponding to the respective level shift elements 20a and 20b. This configuration can enhance the gate threshold voltage of the parasitic n-type MOSFET, so as to suppress the operation of the parasitic n-type MOSFET with no necessity of making a great change of the fundamental characteristics of the field plate (10, 11, 12, 13), as compared with a case of using a field plate having a constant distance from each of the respective isolation regions 6a and 6b and the voltage blocking region 8.

### Sixth Embodiment

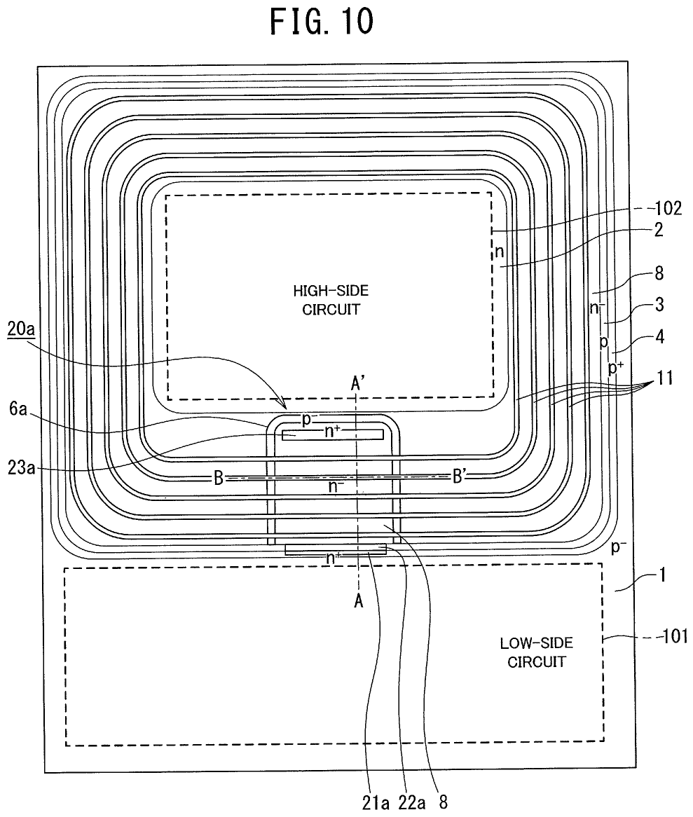

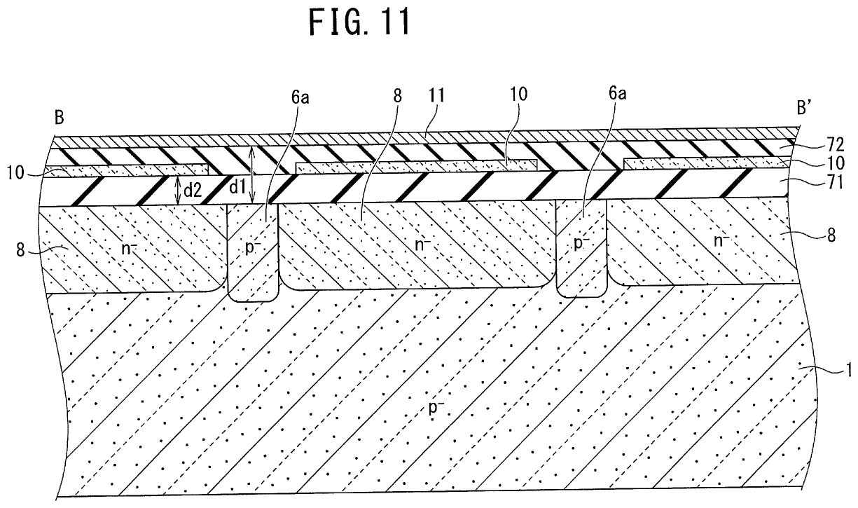

FIG. 10 is a plan view illustrating a semiconductor device according to a sixth embodiment. A cross-sectional view taken along line A-A′ in FIG. 10 is common to that of FIG. 3. FIG. 11 is a cross-sectional view taken long line B-B′in FIG. 10. As illustrated in FIG. 3, FIG. 10, and FIG. 11, the semiconductor device according to the sixth embodiment differs from the semiconductor device according to the first embodiment in that the field plate (10, 11) has a capacitive field plate structure, which is also referred to as a multiple floating field plate (MFFP) structure.

As illustrated in FIG. 11, the field plate (10, 11) includes the first layer 10 and the second layer 11 arranged over the first layer 10. The second layer 11 has a multiple circular and concentric planar pattern, as illustrated in FIG. 10. The first layer 10, which is hidden under the second layer 11 in FIG. 10, has a substantially multiple circular and concentric planar pattern along the second layer 11.

As illustrated in FIG. 11, the first layer 10 is provided over the voltage blocking region 8, while the first layer 10 is selectively (locally) divided at the part over the isolation region 6a. The second layer 11 is provided over the voltage blocking region 8 and the isolation region 6a. A potential of each of the first layer 10 and the second layer 11 is a floating potential. No vias for connecting the first layer 10 and the second layer 11 to each other are provided, and the first layer 10 and the second layer 11 are thus electrically isolated from each other. The first layer 10 and the second layer 11 make a capacitive coupling through the insulating film 72.

The first layer 10 and the second layer 11 each include polysilicon or metal, for example. The first layer 10 and the second layer 11 may include either the same material or different material. The other structures of the semiconductor device according to the sixth embodiment are the same as those of the semiconductor device according to the first embodiment, and overlapping explanations are not repeated below.

The semiconductor device according to the sixth embodiment, in the case in which the field plate (10, 11) has the capacitive field plate structure, has the configuration in which the distance d1 between the isolation region 6a and the second layer 11 is greater than the distance d2 between the voltage blocking region 8 and the first layer 10. This configuration can enhance the gate threshold voltage of the parasitic n-type MOSFET, so as to suppress the operation of the parasitic n-type MOSFET with no necessity of making a great change of the fundamental characteristics of the field plate (10, 11), as compared with a case of using a field plate having a constant distance from each of the isolation region 6a and the voltage blocking region 8.

### Seventh Embodiment

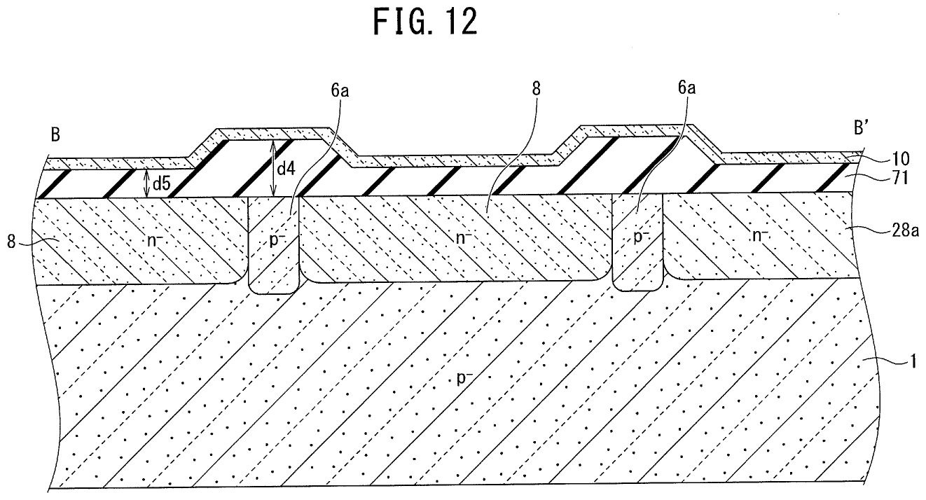

A semiconductor device according to a seventh embodiment differs from the semiconductor device according to the first embodiment illustrated in FIG. 4 in that a thickness d4 of the insulating film 71 located on the top surface of the isolation region 6a is greater than a thickness d5 of the insulating film 71 located on the top surface of the voltage blocking region 8, as illustrated in FIG. 12.

The field plate 10 is provided to have a corrugated shape in cross section on the top surface side of the insulating film 71 so as to conform to the shape of the insulating film 71 having the respective thicknesses d4 and d5. The field plate 10 has a single-layer structure. The field plate 10 includes polysilicon or metal, for example. The field plate 10 may have a resistive field plate structure with a spiral planar pattern, or may have a capacitive field plate structure with a concentric planar pattern. The other structures of the semiconductor device according to the seventh embodiment are the same as those of the semiconductor device according to the first embodiment, and overlapping explanations are not repeated below.

The semiconductor device according to the seventh embodiment has the configuration in which the distance d4 between the isolation region 6a and the field plate 10 is greater than the distance d5 between the voltage blocking region 8 and the field plate 10. This configuration can enhance the gate threshold voltage of the parasitic n-type MOSFET, so as to suppress the operation of the parasitic n-type MOSFET with no necessity of making a great change of the fundamental characteristics of the field plate 10, as compared with a case of using a field plate having a constant distance from each of the isolation region 6a and the voltage blocking region 8.

### Eighth Embodiment

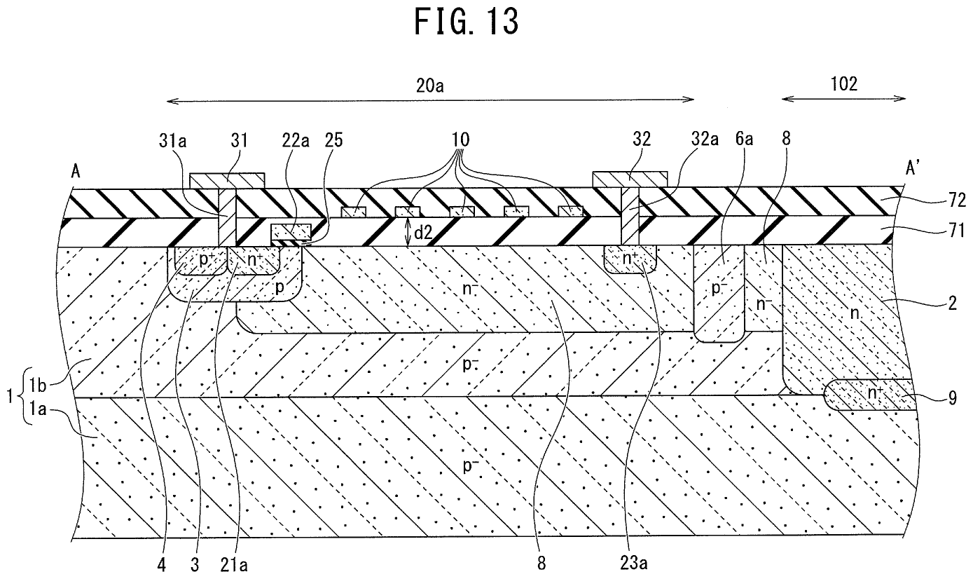

A semiconductor device according to an eighth embodiment differs from the semiconductor device according to the first embodiment illustrated in FIG. 3 in that the base body 1 includes a p⁻-type semiconductor substrate 1a and a p⁻-type epitaxial layer 1b provided on the semiconductor substrate 1a, as illustrated in FIG. 13. The semiconductor device according to the eighth embodiment further differs from the semiconductor device according to the first embodiment illustrated in FIG. 3 in including an n⁺-type buried layer 9 having a higher impurity concentration than the well region 2 so as to be in contact with the bottom surface of the well region 2.

The field plate of the semiconductor device according to the eighth embodiment has substantially the same structure as the field plate (10, 11, 12) of the semiconductor device according to the first embodiment. The other structures of the semiconductor device according to the eighth embodiment are the same as those of the semiconductor device according to the first embodiment, and overlapping explanations are not repeated below.

The semiconductor device according to the eighth embodiment has the configuration in which the distance d1 between the isolation region 6a and the respective second layers 11 and 12 is greater than the distance d2 between the voltage blocking region 8 and the first layer 10, as in the case of the semiconductor device according to the first embodiment illustrated in FIG. 4. This configuration can enhance the gate threshold voltage of the parasitic n-type MOSFET, so as to suppress the operation of the parasitic n-type MOSFET with no necessity of making a great change of the fundamental characteristics of the field plate (10, 11, 12), as compared with a case of using a field plate having a constant distance from each of the isolation region 6a and the voltage blocking region 8.

### Ninth Embodiment

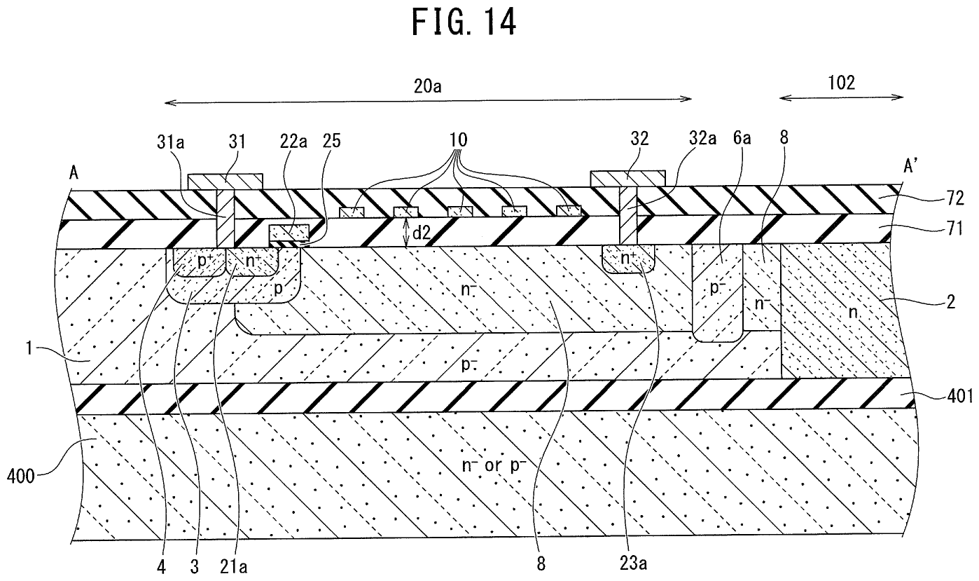

A semiconductor device according to a ninth embodiment differs from the semiconductor device according to the first embodiment illustrated in FIG. 3 in being implemented by a silicon-on-insulator (SOI) substrate, as illustrated in FIG. 14. The semiconductor device according to the ninth embodiment includes a support substrate 400 of n⁻-type or p⁻-type. An insulating film 401 such as an oxide film is deposited on the top surface of the support substrate 400. The p⁻-type base body 1 is deposited on the top surface of the insulating film 401.

The field plate of the semiconductor device according to the ninth embodiment has substantially the same structure as the field plate (10, 11, 12) of the semiconductor device according to the first embodiment. The other structures of the semiconductor device according to the ninth embodiment are the same as those of the semiconductor device according to the first embodiment, and overlapping explanations are not repeated below.

The semiconductor device according to the ninth embodiment has the configuration in which the distance d1 between the isolation region 6a and the respective second layers 11 and 12 is greater than the distance d2 between the voltage blocking region 8 and the first layer 10, as in the case of the semiconductor device according to the first embodiment illustrated in FIG. 4. This configuration can enhance the gate threshold voltage of the parasitic n-type MOSFET, so as to suppress the operation of the parasitic n-type MOSFET with no necessity of making a great change of the fundamental characteristics of the field plate (10, 11, 12), as compared with a case of using a field plate having a constant distance from each of the isolation region 6a and the voltage blocking region 8.

### Other Embodiments

As described above, the invention has been described according to the first to ninth embodiments, but it should not be understood that the description and drawings implementing a portion of this disclosure limit the invention. Various alternative embodiments of the present invention, examples, and operational techniques will be apparent to those skilled in the art from this disclosure.

For example, while the semiconductor device according to the first embodiment is illustrated above with the case in which each chip includes the high-side circuit 102 for one phase, each chip may include high-side circuits for plural phases (three phases, for example). The same can also be applied to the second to eighth embodiments.

Further, while the semiconductor device according to the first embodiment is illustrated above with the case in which the first layer 10 is divided and the second layers 11 and 12 are provided over the isolation region 6a along all of the spiral lines in the direction perpendicular to the extending direction of the spiral of the field plate (10, 11, 12), this structure is not necessarily applied to all of the spiral lines. For example, the first layer 10 may be divided and the second layers 11 and 12 may be provided over the isolation region 6a in a part on the inner circumferential side, which is on the high-potential side, of the spiral lines in the direction perpendicular to the extending direction of the spiral of the field plate (10, 11, 12). Alternatively, the first layer 10 is not necessarily divided or the respective second layers 11 and 12 are not necessarily provided over the isolation region 6a in a part on the outer circumferential side, which is on the low-potential side. The same can also be applied to the second to eighth embodiments.

Further, while the respective semiconductor devices according to the first to ninth embodiments are illustrated above with the HVIC, the present invention can also be applied to a semiconductor device other than the HVIC.

The respective configurations disclosed in the first to ninth embodiments of the present invention and the respective modified examples can be combined together as necessary within a range without contradicting each other. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A semiconductor device comprising:
a base body of a first conductivity-type;
a first well region of a second conductivity-type provided in the base body and including a high-side circuit;
a first voltage blocking region of the second conductivity-type having a lower impurity concentration than the first well region and provided into a circular state along a circumference of the first well region;
a second voltage blocking region of the first conductivity-type provided into a circular state in contact with the first voltage blocking region on an outer circumferential side of the first voltage blocking region;
a first level shift element provided to encompass a part of the first voltage blocking region;
a first isolation region of the first conductivity-type provided to surround a circumference of the first level shift element; and
a field plate provided over the first voltage blocking region and the first isolation region with an insulating film interposed, the field plate having a first distance from the first isolation region greater than a second distance from the first voltage blocking region.

2. The semiconductor device of claim 1, wherein the field plate is elongated across an upper side of the first level shift element with the second distance.

3. The semiconductor device of claim 1, wherein the field plate is elongated across an upper side of each of the first voltage blocking region and the first level shift element with the first distance.

4. The semiconductor device of claim 1, further comprising:
a second level shift element provided to encompass another part of the first voltage blocking region; and
a second isolation region of the first conductivity-type provided to surround a circumference of the second level shift element,
wherein the field plate is elongated across an upper side of each of the first voltage blocking region, the first level shift element, the second isolation region, and the second level shift element with the first distance.

5. The semiconductor device of claim 1, wherein the field plate incudes:
a first layer provided over the first voltage blocking region while being divided over the first isolation region; and
a second layer provided over the first isolation region.

6. The semiconductor device of claim 5, wherein the first layer is electrically connected to the second layer.

7. The semiconductor device of claim 5, wherein the first layer includes polysilicon, and the second layer includes metal.

8. The semiconductor device of claim 5, wherein the second layer is locally provided over the first isolation region.

9. The semiconductor device of claim 5, wherein the second layer is provided over the first voltage blocking region.

10. The semiconductor device of claim 1, wherein:
the insulating film has a greater thickness at a part on the first isolation region than at a part on the first voltage blocking region; and
the field plate has a single-layer having a corrugated pattern in cross section.

11. The semiconductor device of claim 1, wherein the field plate has a spiral-shaped planar pattern.

12. The semiconductor device of claim 11, wherein:
one end of the spiral-shaped planar pattern on an inner circumferential side is connected to a first potential; and
another end of the spiral-shaped planar pattern on an outer circumferential side is connected to a second potential lower than the first potential.

13. The semiconductor device of claim 1, wherein the field plate has a concentric planar pattern.

14. The semiconductor device of claim 13, wherein a potential of the field plate is a floating potential.

15. The semiconductor device of claim 1, wherein the first isolation region has a U-shaped planar pattern having two straight parts with ends connected to the second voltage blocking region.
